(19) United States
(12) Patent Application Publication
(10) Pub. No.: US 2019/0122897 A1
(43) Pub. Date: Apr. 25, 2019

(54) Low Profile Electronic System Method and Apparatus

(71) Applicant: Global Circuit Innovations Inc., Colorado Springs, CO (US)

(72) Inventor: Timothy Mark Barry, Colorado Springs, CO (US)

(73) Assignee: Global Circuit Innovations Inc., Colorado Springs, CO (US)

(21) Appl. No.: 15/792,472

(22) Filed: Oct. 24, 2017

(51) Int. Cl. H01L 21/48; H01L 23/538

(52) U.S. Cl. CPC H01L 21/485; H01L 21/4853; H01L 23/5389; H01L 23/5382; H01L 23/5386; H01L 21/4867

(57) ABSTRACT

A method is provided. The method includes one or more of forming a cutout in a substrate, positioning a die comprising one or more bond pads in a coplanar orientation with the substrate in the cutout, securing the die in the cutout, and 3D printing one or more bond connections between the one or more bond pads and one or more connection points of the substrate or one or more bond pads of another die secured to the substrate.

### FIELD

The present invention is directed to methods and apparatuses for low profile circuits. In particular, the present invention is directed to methods and apparatuses for packaging semiconductor dice and interconnection circuits in extremely low profile systems.

### BACKGROUND

Electronic circuit miniaturization has been proceeding constantly, with newer technologies and process improvements yielding notable improvements. Surface-mount technology (SMT) is a method for producing electronic circuits in which the components are mounted or placed directly onto the surface of printed circuit boards (PCBs). An electronic device so made is called a surface-mount device (SMD). In the industry it has largely replaced the through-hole technology construction method of fitting components with wire leads into holes in the circuit board. Both technologies can be used on the same board, with the through-hole technology used for components not suitable for surface mounting such as large transformers and heatsinked power semiconductors.

An SMT component is usually smaller than its through-hole counterpart because it has either smaller leads or no leads at all. It may have short pins or leads of various styles, flat contacts, a matrix of solder balls (BGAs), or terminations on the body of the component.

Surface-mount technology was developed in the 1960s and became widely used in the late 1980s. Much of the pioneering work in this technology was by IBM. The design approach first demonstrated by IBM in 1960 in a small-scale computer was later applied in the Launch Vehicle Digital Computer used in the Instrument Unit that guided all Saturn D3 and Saturn V vehicles. Components were mechanically redesigned to have small metal tabs or end caps that could be directly soldered to the surface of the PCB. Components became much smaller and component placement on both sides of a board became far more common with surface mounting than through-hole mounting, allowing much higher circuit densities. Often only the solder joints hold the parts to the board, in rare cases parts on the bottom or “second” side of the board may be secured with a dot of adhesive to keep components from dropping off inside reflow ovens if the part has a large size or weight. Adhesive is sometimes used to hold SMT components on the bottom side of a board if a wave soldering process is used to solder both SMT and through-hole components simultaneously. Alternatively, SMT and through-hole components can be soldered together without adhesive if the SMT parts are first reflow-soldered, then a selective solder mask is used to prevent the solder holding the parts in place from reflowing and the parts floating away during wave soldering. Surface mounting lends itself well to a high degree of automation, reducing labor cost and greatly increasing production rates. SMDs can be one-quarter to one-tenth the size and weight, and one-half to one-quarter the cost of equivalent through-hole parts.

### SUMMARY

In accordance with embodiments of the present invention, a method is provided. The method includes one or more of forming a cutout in a substrate, positioning an extracted die in a coplanar orientation with the substrate in the cutout, and securing the extracted die in the cutout. The extracted die has been removed from a previous packaged integrated circuit and includes one or more original bond pads and one or more original ball bonds on the one or more original bond pads. The method also includes 3D printing one or more bond connections between the one or more bond pads and one or more connection points of the substrate or one or more bond pads of another die secured to the substrate.

In accordance with another embodiment of the present invention, a circuit is provided. The circuit includes one or more of a planar substrate including a plurality of connection points, a die including a plurality of bond pads, coplanarly secured within a cutout in the substrate, and a plurality of bond connections between the bond pads and the connection points, the bond connections conforming to all surfaces of the substrate and the die between the bond pads and the connection points.

In accordance with yet another embodiment of the present invention, a circuit is provided. The circuit includes one or more of a planar printed circuit board including connection points and a cutout, an extracted die removed from a previous packaged integrated circuit, and encapsulant to secure the die within the cutout in a generally coplanar orientation with the printed circuit board. The extracted die includes original bond pads and one or more original ball bonds on the original bond pads. The circuit also includes bond connections between the original bond pads and one of the connection points or other bond pads of another die, the bond connections conforming to all surfaces of the printed circuit board, the extracted die, and the other die between the other bond pads and the connection points.

An advantage of the present invention is it allows for greatly reduced circuit height by planarly embedding a die in a circuit board or substrate, and utilizing 3D printed bond connections in lieu of conventional bond wires. This results in a package with the approximate thickness of a die.

Another advantage of the present invention is it eliminates solder connections in a die/substrate circuit. Because conventional solder is not present, there are no issues related to lead content in solder or solder bridging problems.

Yet another advantage of the present invention is by replacing conventional bond wires with 3D printed bond connections, reliability is greatly improved. Conventional bond wires have a free mass that provides mechanical stress to ball bonds and bond pad interfaces when under shock and vibration conditions. Additionally, conventional wire bonding processes with Gold (Au) ball bonds on Aluminum (Al) bond pads are known to have reliability problems that are accelerated at high temperatures. 2D printed bond connections have neither of these problems since they are conformal to interconnected surfaces (i.e. no free mass) and the metallic composition includes Nickel and Silver instead of Gold. Additionally and significantly, conventional bond wires have a bend radius and height that limits packaging to taller structures than the present invention, thus impacting extremely flat packing options for the circuit.

Additional features and advantages of embodiments of the present invention will become more readily apparent from the following description, particularly when taken together with the accompanying drawings.

### BRIEF DESCRIPTION OF THE DRAWINGS

FIG. 1 is a diagram illustrating a Top View of Embedded Dies in a Substrate System in accordance with embodiments of the present invention.

FIG. 2A is a diagram illustrating a side view of Preparing a Cutout in a Printed Circuit Board or Substrate in accordance with embodiments of the present invention.

FIG. 2B is a diagram illustrating a side view of Positioning a Die in a Cutout in accordance with embodiments of the present invention.

FIG. 2C is a diagram illustrating a side view of Application of KAPTON Tape in accordance with embodiments of the present invention.

FIG. 2D is a diagram illustrating a side view of Filling Cutout Voids in accordance with embodiments of the present invention.

FIG. 2E is a diagram illustrating a side view of Removing KAPTON Tape in accordance with embodiments of the present invention.

FIG. 2F is a diagram illustrating a side view of 3D Printed Bond Connections in accordance with embodiments of the present invention.

FIG. 3A is a diagram illustrating a side view of Preparing a Cutout in accordance with embodiments of the present invention.

FIG. 3B is a diagram illustrating a side view of Positioning a Die in a Cutout in accordance with embodiments of the present invention.

FIG. 3C is a diagram illustrating a side view of Filling Cutout Voids in accordance with embodiments of the present invention.

FIG. 3D is a diagram illustrating a side view of 3D Printed Bond Connections in accordance with embodiments of the present invention.

FIG. 4A is a diagram illustrating a side view of a Printed Bond Connection for a Level Die in accordance with a first embodiment of the present invention.

FIG. 4B is a diagram illustrating a side view of a Printed Bond Connection for a Level Die in accordance with a second embodiment of the present invention.

FIG. 4C is a diagram illustrating a side view of a Printed Bond Connection for a Recessed Die in accordance with a first embodiment of the present invention.

FIG. 4D is a diagram illustrating a side view of a Printed Bond Connection for a Recessed Die in accordance with a second embodiment of the present invention.

FIG. 4E is a diagram illustrating a side view of a Printed Bond Connection for a Recessed Die in accordance with a third embodiment of the present invention.

FIG. 4F is a diagram illustrating a side view of a Printed Bond Connection for a Recessed Die in accordance with a fourth embodiment of the present invention.

FIG. 4G is a diagram illustrating a side view of a Printed Bond Connection for an Elevated Die in accordance with a first embodiment of the present invention.

FIG. 4H is a diagram illustrating a side view of a Printed Bond Connection for an Elevated Die in accordance with a second embodiment of the present invention.

FIG. 5 is a flowchart illustrating a Low Profile System Assembly Process in accordance with a first embodiment of the present invention.

FIG. 6 is a flowchart illustrating a Low Profile System Assembly Process in accordance with a second embodiment of the present invention.

### DETAILED DESCRIPTION

The present invention is directed to methods and circuits for producing very low profile circuits. By matching the thickness of one or more dice with a substrate surrounding the one or more dice, and 3D printing bond connections between the one or more dice and the substrate, an extremely low profile circuit may be created. Although various forms of printed circuits and substrates may have low profile conformal connections, these are generally provided to interposers or dice in a flip chip or other compact arrangement. Thus, although relatively low profile “stacked circuits” may be created, they are still significantly thicker than a single printed circuit board or substrate.

In some embodiments conventional bond wires are used to interconnect bond pads of the one or more dice with other bond pads of other dice or connection points on the substrate. Bond wires have the disadvantage of adding height to the circuit as well as undesirable levels of reliability and vulnerability to shock and vibration. The present invention eliminates bond wires by 3D printing bond connections that may include bond conductors and bond insulators. 3D printed bond connections have the additional advantage of able to being crossed while remaining conformal to the underlying die surfaces or substrate surfaces. A bond insulator printed between bond conductors of two traces can electrically isolate the two bond conductors and allow crossing of 3D printed bond connections. Therefore what is needed is a method in circuit to provide extremely low total circuit thickness without utilizing bond wires or stacking components.

In the context of the present application, a “die” may either be a bare (new production) die either in singular form or cut into an individual die from a semiconductor wafer, or an extracted die. An extracted die is a die removed by any of several known processes from a previous packaged integrated circuit. An extracted die is a fully functional die. When an extracted die is removed from the previous integrated circuit package, some original bond wires likely have been removed and one or more original ball bonds remain. In current technology packaged integrated circuits, the vast majority of bond wire interconnections are made with Au thermosonic ball bonding. Each previously used original bond pad of an extracted die may have an original ball bond present, although one or more unbonded bond pads may not have an original ball bond present.

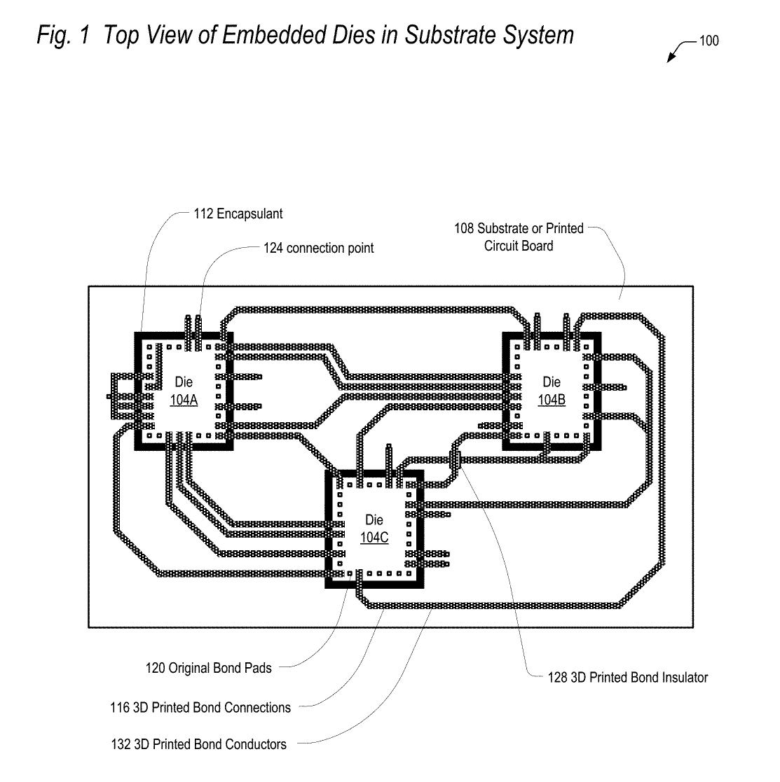

Referring now to FIG. 1, a diagram illustrating a top view of embedded dies in a substrate system 100 in accordance with embodiments of the present invention is shown. Substrate system 100 includes one or more semiconductor dice 104. The system 100 illustrated in FIG. 1 includes three dice, identified as die 104A, die 104B, and die 104C. Any number of dice 104 may be present in substrate system 100, and the dice may be of the same type or any number of different types. However in the preferred embodiment, all of the dice 104 are the similar thickness in order to minimize total height of the substrate system 100 as well as height variances between dice 104 and the substrate 108. Each die 104 includes some number of bond pads 120, which are semiconductor bond pads known in the art and inherently present as part of each die 104. In most embodiments bond pads 120 are Aluminum (Al), but in other embodiments may be any combination of suitable conductive materials including Copper (Cu), Gold (Au), or Nickel (Ni).

Substrate system 100 includes a substrate or printed circuit board 108. Substrate or printed circuit board 108 may be made from any known materials as long as sufficient rigidity is achieved when the substrate or printed circuit board 108 is approximately the same thickness as dice 104. Therefore, the substrate or printed circuit board 108 may be constructed from FR-4, ceramic, cured epoxy, fiberglass, carbon fiber, or any other suitable material. Although in most embodiments, the top surface of substrate or printed circuit board 108 is mostly nonconductive, in some embodiments the top surface may be conductive. In those cases, if it is desirable to interconnect bond pads of the dice 104 with the conductive surface of the substrate or printed circuit board 108, then only 3D printed bond conductors 132 are required. In other cases, if it is desirable to isolate bond pads of the dice 104 from a conductive surface of the substrate or printed circuit board 108, then 3D printed bond conductors 132 applied over 3D printed bond insulators 128 would be provided.

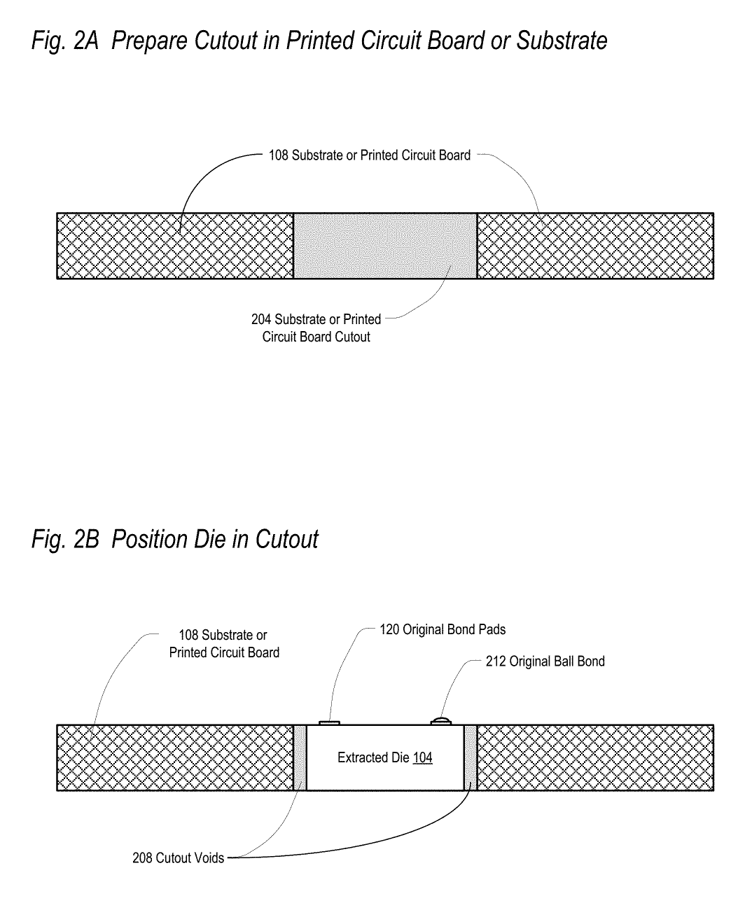

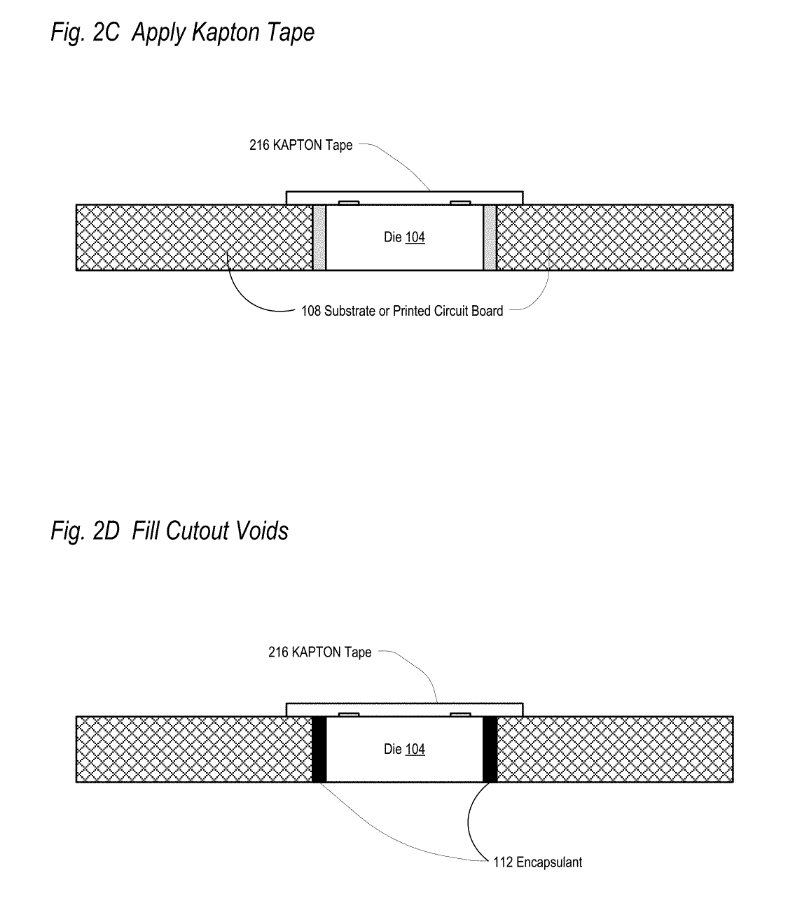

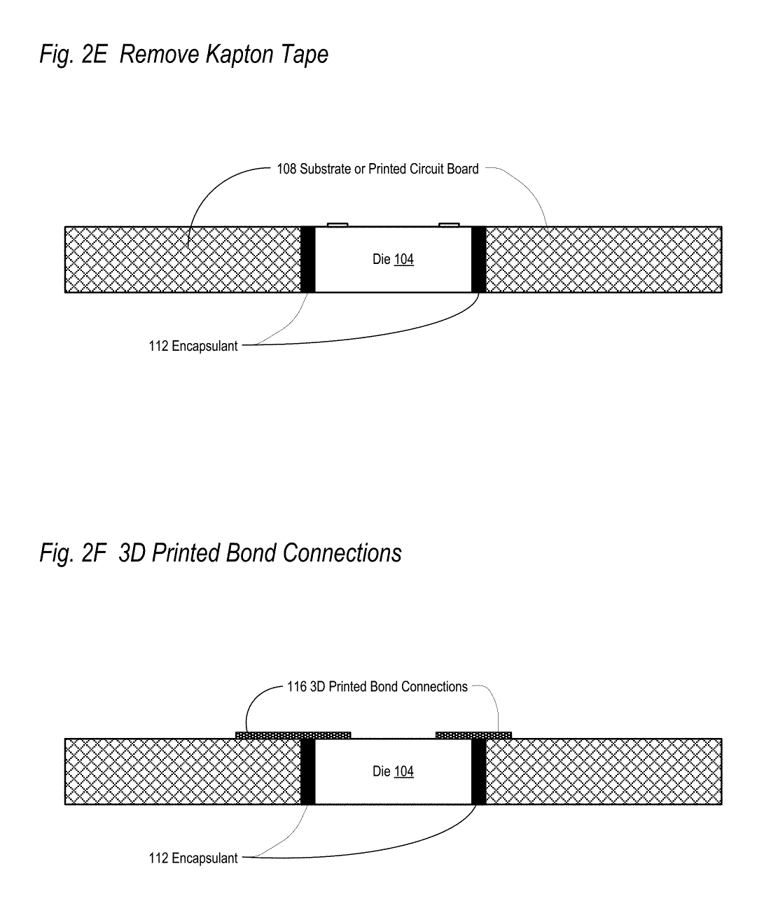

Not shown in FIG. 1 is a cutout in the substrate or printed circuit board 108 provided for each die 104. The cutout will be described in more detail with respect to FIG. 2A. In most embodiments, it is necessary to inject a form of encapsulant 112 into the cutout between the substrate or printed circuit board 108 and the die 104, in order to secure the die 104 to the substrate or printed circuit board 108. The encapsulant 112 will be described in more detail with respect to FIG. 2D.

The substrate or printed circuit board 108 may have no inherent electrical connections by itself, including traces, connection points 124, or vias known in the art. In some embodiments, the substrate or printed circuit board 108 may have any combination of traces, connection points 124, or vias. Connection points 124 denotes any connection location on the substrate or printed circuit board 108 for any purpose, including a bond pad, a via, a component pad such as for a discrete component including resistors, capacitors, inductors, diodes, or transistors, a connector pad for any sort of connector, or any other type of electrical connection point.

Substrate system 100 also includes one or more 3D printed bond connections 116. 3D printed bond connections 116 are as described in related parent application Ser. No. 14/142,823 (Docket GCP0004 US), which is included by reference herein for all purposes. In some embodiments, 3D printed bond connections 116 include only 3D printed bond conductors 132. In other embodiments, 3D printed bond connections 116 also include one or more 3D printed bond insulators 128. In the exemplary substrate system 100 illustrated in FIG. 1, generally only 3D printed bond conductors 132 are present. However FIG. 1 illustrates one of the advantages of 3D printed bond connections 116 of the present invention, where it may be necessary to cross 3D printed bond connections 116 and one or more points. FIG. 1 illustrates one such crossing, where a first 3D printed bond conductor 132 is applied between die 104B and die 104C. Next, a 3D printed bond insulator 128 is provided where a second 3D printed bond conductor 132 will cross the first 3D printed bond conductor 132. In this way, various connections between dice 104 and the substrate or printed circuit board 108 may be provided without utilizing a multilayer substrate or printed circuit board 108 construction and thereby facilitating an extremely flat or thin overall substrate system 100 profile.

3D printers are able to precisely deposit insulating 128 or conducting 132 material on complex shapes, and are able to build up or layer the insulating or conducting material to a precise thickness. 3D printers include a spray head, which applies bond insulator 128 material or bond conductor 132 material to selected areas. 3D printers typically deposit material in layers, and build up a desired thickness of material by depositing multiple layers. The 3D printer is computer controlled equipment, and sprays material according to a file or files prepared beforehand designating specific locations that material will be applied to.

In one embodiment, the 3D printer uses an extrusion process to apply either the bond insulator material 128 or the bond conductor material 132, or both. The extrusion process, sometimes referred to as Fused Deposition Modeling (FDM) uses a heated nozzle to extrude molten material.

In another embodiment, the 3D printer uses a Colorjet Printing (CJP) process to apply either the bond insulator material 128 or the bond conductor material 132, or both. The CJP process utilizes an inkjet-based technology to spread fine layers of a dry substrate material. The dry substrate is most often in a powder form. The inkjet applies a binder to the substrate after applying the dry substrate material in order to solidify and cure the dry substrate.

In the preferred embodiment, the 3D printer uses a selective laser sintering process. Either bond insulator material 128 or bond conductor material 132 is applied in powder form. The bond insulator material 128 is a material able to be applied in powder form or extruded, and is generally a polymer or plastic. However, any material having suitable insulation properties, able to adhere to surfaces of the die 104, encapsulant 112, and substrate or printed circuit board 108, and able to be applied with a 3D printer material spray head is suitable as bond insulator material 128.

The bond conductor material 132 is also a material able to be applied in powder form or extruded, and includes at least conductive metal and possibly polymer or plastic content in order to provide elastomeric or resilient properties. In the preferred embodiment, the metal content is silver. In other embodiments, the material may include alone or in combination gold, aluminum, or copper.

Referring now to FIG. 2A, a diagram illustrating a side view of preparing a cutout 204 in a printed circuit board or substrate 108 in accordance with embodiments of the present invention is shown. In order to achieve a thinnest possible substrate system 100, it is necessary to provide a cutout 204 in the substrate or printed circuit board 108. In the embodiment illustrated, the cutout 204 is completely through the substrate or printed circuit board 108, and the dimensions of the cutout 204 are slightly greater than the X-Y dimensions of a die 104 intended to be secured within the cutout 204. The cutout 204 may be formed using any known processes appropriate for creating square or rectangular close tolerance voids in the substrate or printed circuit board 108, including laser cutting.

If the die 104 has a significantly different thickness than the substrate or printed circuit board 108, it will be desirable to reduce the thickness of the thicker of the die 104 or the substrate or printed circuit board 108. In one embodiment, when the die 104 thickness is greater than the desired substrate or printed circuit board 108 thickness, the die 104 may be thinned to the PCB thickness(or thinner), down to approximately four mils or 0.004 inches.

Referring now to FIG. 2B, a diagram illustrating a side view of positioning a die 104 in a cutout 204 in accordance with embodiments of the present invention is shown. Die 104 may be any form of semiconductor die, including logic devices or linear or analog devices. Die 104 includes one or more bond pads 120 or original bond pads 120, which are arranged on one surface of the die 104. In most embodiments, bond pads 120 are arranged around the periphery of die 104. However, in other embodiments bond pads 120 may be arranged in any fashion on the surface of die 104. In such cases, it is necessary that spacing between bond pads 120 allows 3D printed bond connections 116 to be provided with enough clearance to prevent electrical shorting between bond pads 120 or 3D printed bond connections 116 and bond pads 120. If the die 104 is an extracted die 104, one or more original ball bonds 212 may be present on the original bond pads 120. However, at this stage any original bond wires will have been already removed from each of the original ball bonds 212. With the die 104 properly positioned, the die 104 is centered within the cutout 204, and the backside of the die 104 (i.e. the surface of the die 104 opposite to the surface including the bond pads 120) is in the same plane as the backside of the substrate or printed circuit board 108. Therefore, the die 104 is generally coplanar with the substrate or printed circuit board 108. Also, with the die 104 properly positioned within the cutout 204, cutout voids 208 are on each side of the die 104. Although original ball bonds 212 are only illustrated in FIG. 2B, it should be understood they may be present in any embodiment or assembly step illustrated herein, and are not specifically shown in order to more clearly show the assembly or process step being specifically illustrated or described.

Referring now to FIG. 2C, a diagram illustrating a side view of application of KAPTON Tape 216 in accordance with embodiments of the present invention is shown. KAPTON tape 216 is commonly used to secure electrical components during soldering or other assembly processes. In the present invention, KAPTON tape 216 temporarily secures a circuit side of the die 104 within the cavity 204 of the substrate or printed circuit board 108. Therefore, the KAPTON tape 216 is larger than the cavity 204, and extends to surfaces on the backside of the substrate or printed circuit board 108. The die 104 makes contact with an adhesive side of the KAPTON tape 216. The circuit side of the die 104 is the side of the die 104 where the bond pads 120 are located. It is important to apply the KAPTON tape 216 to the circuit side of the die 104 in order to simplify application of backfill compounds and printed bond insulators/conductors.

Referring now to FIG. 2D, a diagram illustrating a side view of filling cutout voids 208 in accordance with embodiments of the present invention is shown. In order to secure the die 104 within the cavity 204, it is necessary to fill the cutout voids 208 with an encapsulant 112, as described with reference to FIG. 1. In the preferred embodiment, the encapsulant 112 completely occupies the cutout voids 208, up to the lower of the top surface of the die 104 and the substrate or printed circuit board 108. After injecting the encapsulant 112 into the cutout voids 208, the encapsulant 112 should be cured before proceeding further, according to specifications of the encapsulant 112 that is used. Encapsulant 112 includes any suitable filler that can secure die 104 within the cutout 204, including die attach adhesives, epoxies, polymers, and other materials. In most embodiments, encapsulant 112 is a non-conductive material. However in other embodiments, encapsulant 112 may be a conductive material. In such cases, 3D printed bond insulators 128 may be necessary to prevent electrical conduction between 3D printed bond conductors 132 and a conductive encapsulant 112.

Referring now to FIG. 2E, a diagram illustrating a side view of removing KAPTON Tape 216 in accordance with embodiments of the present invention is shown. After the encapsulant 112 has at least partially cured, the KAPTON tape 216 is removed from the rear side of the die 104 and substrate or printed circuit board 108. The presence of the KAPTON tape 216 blocks the encapsulant 112 from flowing below the rear surface of the die 104 and the substrate or printed circuit board 108. Depending on properties of the encapsulant 112, the KAPTON tape 216 is removed either while the encapsulant 112 is curing, or after the encapsulant 112 has fully cured.

Referring now to FIG. 2F, a diagram illustrating a side view of 3D printed bond connections 116 in accordance with embodiments of the present invention is shown. 3D printed bond connections 116 include at least a 3D printed bond conductor 132, and in some embodiments also includes a 3D printed bond insulator 128 between the 3D printed bond conductor 132 and the top surface of the substrate or printed circuit board 108. Following application of all required 3D printed bond connections 116 the substrate system 100 is complete.

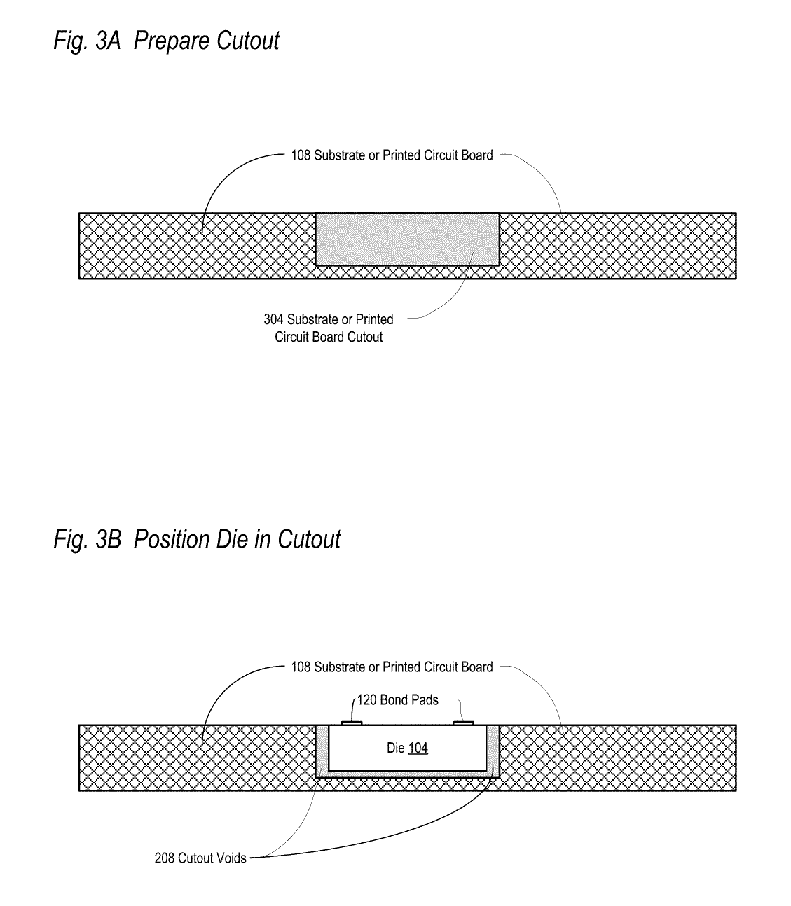

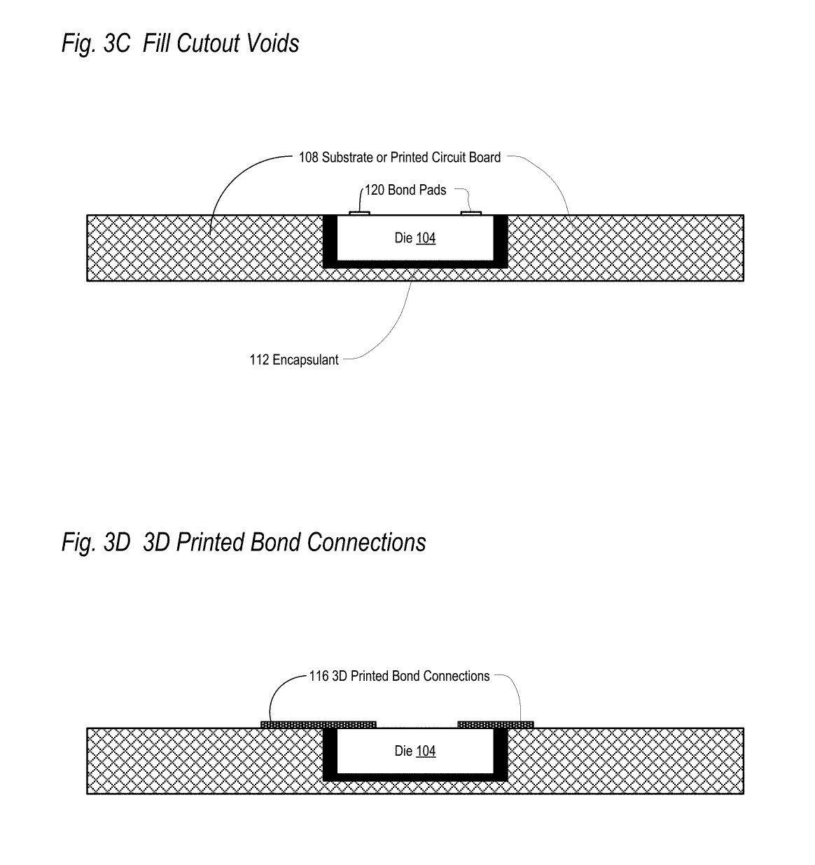

Referring now to FIG. 3A, a diagram illustrating a side view of preparing a cutout 204 in accordance with embodiments of the present invention is shown. In the embodiment of FIG. 3A, the substrate or printed circuit board cutout 304 does not extend through the entire thickness of the substrate or printed circuit board 108. This embodiment may be useful in cases where the substrate or printed circuit board 108 is incapable of being thinned less than a current thickness that is still greater than a die 104 thickness. Therefore, the depth of cutout 304 is approximately the same as the thickness of the die 104.

Referring now to FIG. 3B, a diagram illustrating a side view of positioning a die 104 in a cutout 304 in accordance with embodiments of the present invention is shown. The die 104 is positioned symmetrically within the cutout 304 such that the die 104 is centered within the cutout 304. Equal-sized cutout voids 208 are present on each side of the die 104, and the die 104 in some embodiments rests upon the bottom of cutout 304. One advantage of this embodiment is that KAPTON tape 216 or other tapes are not required in order to position the die 104 vertically within the cutout 304.

Referring now to FIG. 3C, a diagram illustrating a side view of filling cutout voids 208 in accordance with embodiments of the present invention is shown. Similar to the embodiment illustrated in FIG. 2D, encapsulant 112 is used to fill the cutout voids 208 around the die 104. In one embodiment, the encapsulant 112 is injected in such a way as to provide encapsulant below the die 104 and eliminate pockets below the die 104 where moisture or gases may be trapped. Alternatively, encapsulant 112 below the die 104 may be applied to the cutout 204 prior to positioning the die 104 in the cutout 204. In the preferred embodiment, the top surface of the die 104 or die bond pads 120 are in the same plane as the top surface of substrate or printed circuit board 108 following encapsulant 112 injection.

Referring now to FIG. 3D, a diagram illustrating a side view of 3D printed bond connections 116 in accordance with embodiments of the present invention is shown. Similar to the embodiment illustrated in FIG. 2F, 3D printed bond connections 116 are provided including at least a 3D printed bond conductor 132, and in some embodiments also including a 3D printed bond insulator 128 between the 3D printed bond conductor 132 and the top surface of the substrate or printed circuit board 108. Following application of all required 3D printed bond connections 116 the substrate system 100 is complete.

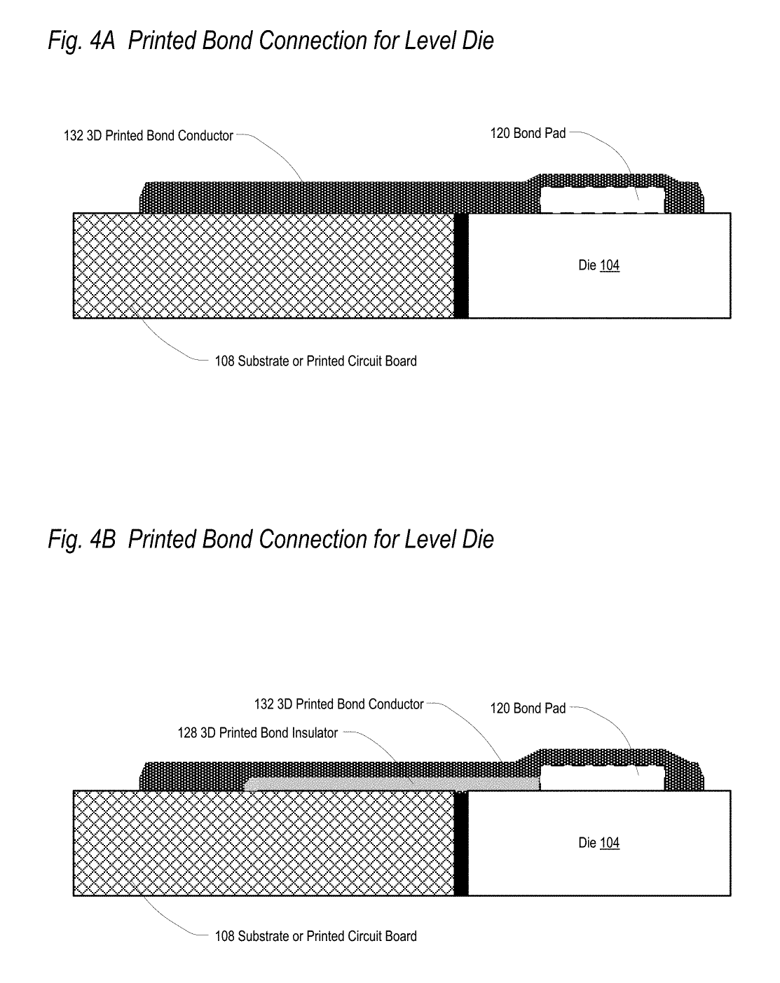

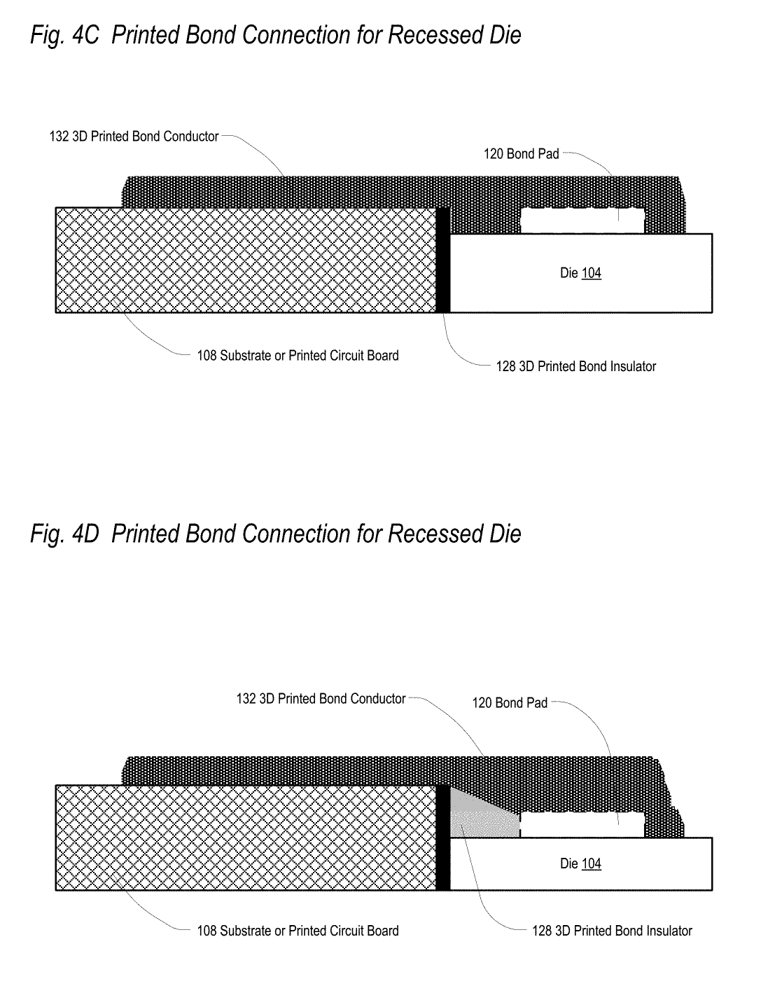

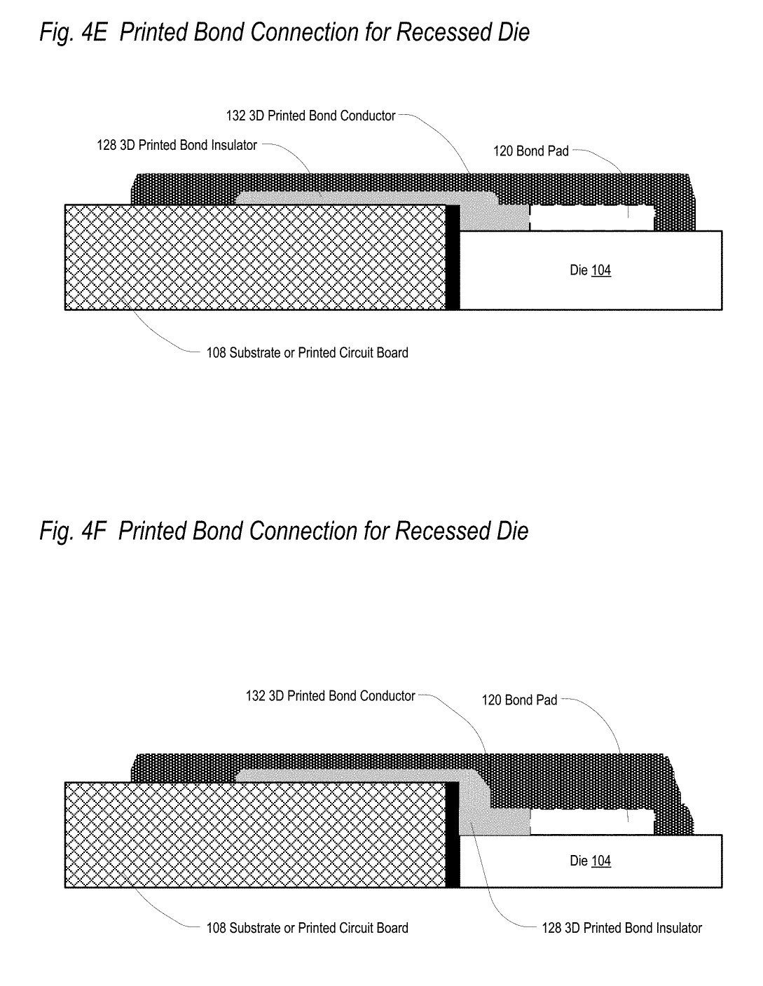

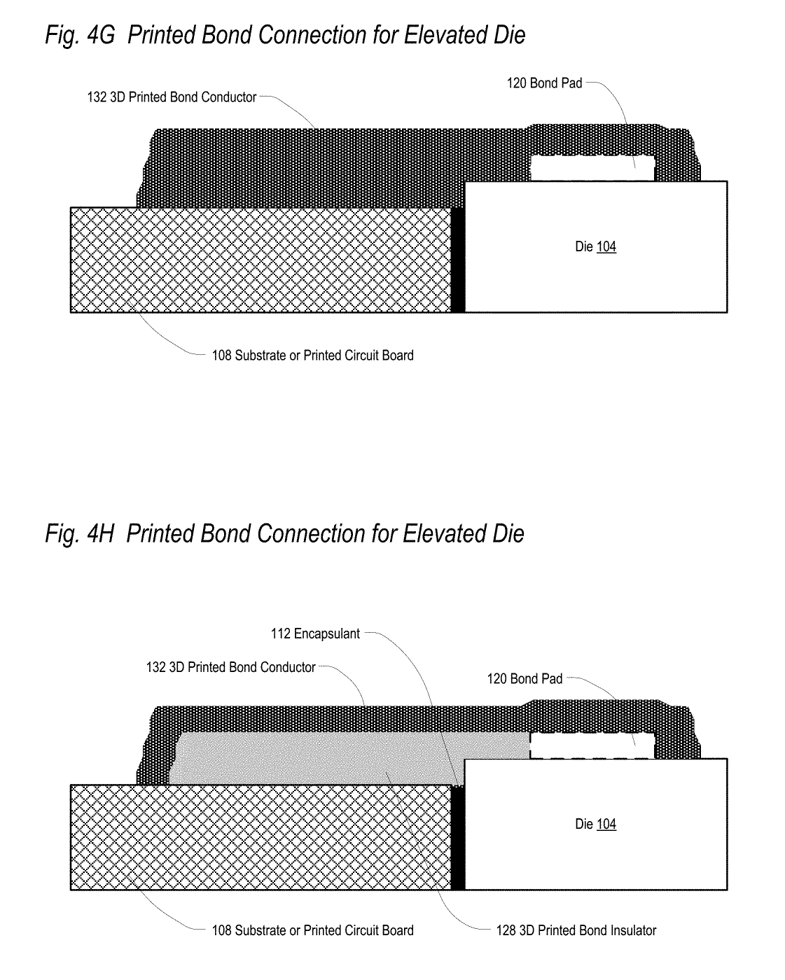

Referring now to FIG. 4A, a diagram illustrating a side view of a printed bond connection 116 for a level die 104 in accordance with a first embodiment of the present invention is shown. A level die 104 is a die wherein the top surface of the die 104 is at the same level as a top surface of the substrate or printed circuit board 108 following application of encapsulant 112. FIG. 4A illustrates an embodiment where only a 3D printed bond conductor 132 is required between a bond pad 120 and either another bond pad 120 of another die 104 or a connection 124 of the substrate or printed circuit board 108. In this case, top surfaces of the die 104 and the substrate or printed circuit board 108 are either non-conductive, or otherwise conductive and desired to be electrically connected to bond pad 120. In the preferred embodiment, the 3D printed bond conductor 132 completely covers bond pad 120 in order to limit or prevent formation of oxides and ingress of contaminants between bond pad 120 and the 3D printed bond conductor 132. The thickness of the 3D printed bond conductor 132 is dependent upon the desired current carrying capacity of the trace attached to the bond pad 120 as well as whether the 3D printed bond conductor 132 needs to be resistant to bonding forces and applying new ball bonds somewhere along the length of the 3D printed bond conductor 132. Typically, the thickness of the 3D printed bond conductor 132 for most applications is less than 2 microns, and preferably 0.5-1 microns.

Referring now to FIG. 4B, a diagram illustrating a side view of a printed bond connection 116 for a level die 104 in accordance with a second embodiment of the present invention is shown. The embodiment illustrated in FIG. 4B is similar to the embodiment illustrated in FIG. 4A, except in this embodiment it is desirable to provide a 3D printed bond insulator 128 over the die 104, encapsulant 112, and substrate or printed circuit board 108 prior to applying a 3D printed bond conductor 132. The 3D printed bond insulator 128 thus prevents electrical conduction between the 3D printed bond conductor 132 and conductive areas of the substrate or printed circuit board 108 and the top surface of the die 104. Typically, the thickness of the 3D printed bond insulator 128 for most applications is less than 2 microns, and preferably 0.5-1 microns.

Referring now to FIG. 4C, a diagram illustrating a side view of a printed bond connection 116 for a recessed die 104 in accordance with a first embodiment of the present invention is shown. FIG. 4C illustrates an embodiment where the substrate or printed circuit board 108 thickness cannot be reduced below a current thickness which is greater than the thickness of a die 104. In this embodiment, a 3D printed bond insulator 128 is initially applied to isolate top surfaces of the die 104 from the 3D printed bond conductor 132. Alternatively, encapsulant 112 may fill the area indicated by the 3D printed bond insulator 128. In some embodiments, there may be no top surfaces of the die 104 that need to be electrically isolated from the 3D printed bond conductor 132. In such cases, only the 3D printed bond conductor 132 may be required, and can also backfill the area shown. FIG. 4C is similar to FIG. 4A illustrates an embodiment where only a 3D printed bond conductor 132 is required between a bond pad 120 and either another bond pad 120 of another die 104 or a connection point 124 of the substrate or printed circuit board 108.

Referring now to FIG. 4D, a diagram illustrating a side view of a printed bond connection 116 for a recessed die in accordance with a second embodiment of the present invention is shown. The embodiment illustrated in FIG. 4D is similar to the embodiment illustrated in FIG. 4C except that the die 104 is recessed below the surface of the substrate or printed circuit 108 to a greater degree. In this case, it may be desirable to provide a ramped backfill as illustrated between the top surface of the substrate or printed circuit board 108 and the top surface of the bond pad 120. In one embodiment, the 3D printed bond insulator may occupy the space, and in another embodiment, the encapsulant 112 may be applied to occupy the space. In general, it is less desirable to have the embodiment illustrated in FIG. 4D since that is likely to result in a thicker substrate system 100.

Referring now to FIG. 4E, a diagram illustrating a side view of a printed bond connection 116 for a recessed die 104 in accordance with a third embodiment of the present invention is shown. FIG. 4E represents an embodiment that is the combination of the embodiments illustrated in FIGS. 4B and 4C. In this embodiment, the 3D printed bond insulator 128 is required between the 3D printed bond conductor 132 and the top surface of the substrate or printed circuit board 108, and the die 104 is recessed.

Referring now to FIG. 4F, a diagram illustrating a side view of a printed bond connection 116 for a recessed die 104 in accordance with a fourth embodiment of the present invention is shown. FIG. 4F represents an embodiment is the combination of the embodiments illustrated in FIGS. 4B and 4D. In this embodiment, the 3D printed bond insulator 128 is required between the 3D printed bond conductor 132 and the top surface of the substrate or printed circuit board 108, and the die 104 is strongly recessed.

Referring now to FIG. 4G, a diagram illustrating a side view of a printed bond connection 116 for an elevated die 104 in accordance with a first embodiment of the present invention is shown. FIG. 4G illustrates an embodiment where the die 104 thickness cannot be reduced below a current thickness which is greater than the thickness of a substrate or printed circuit board 108. In this case, top surfaces of the die 104 and the substrate or printed circuit board 108 are either non-conductive, or otherwise conductive and desired to be electrically connected to bond pad 120. In the preferred embodiment, the 3D printed bond conductor 132 completely covers bond pad 120 in order to limit or prevent formation of oxides and ingress of contaminants between bond pad 120 and the 3D printed bond conductor 132. The thickness of the 3D printed bond conductor 132 is dependent upon the desired current carrying capacity of the trace attached to the bond pad 120 as well as whether the 3D printed bond conductor 132 needs to be resistant to bonding forces and applying new ball bonds somewhere along the length of the 3D printed bond conductor 132.

Referring now to FIG. 4H, a diagram illustrating a side view of a printed bond connection 116 for an elevated die in accordance with a second embodiment of the present invention is shown. The embodiment illustrated in FIG. 4H is similar to the embodiment illustrated in FIG. 4G, except in this embodiment it is desirable to provide a 3D printed bond insulator 128 over the die 104, encapsulant 112, and substrate or printed circuit board 108 prior to applying a 3D printed bond conductor 132. The 3D printed bond insulator 128 thus prevents electrical conduction between the 3D printed bond conductor 132 and conductive areas of the substrate or printed circuit board 108 and the top surface of the die 104.

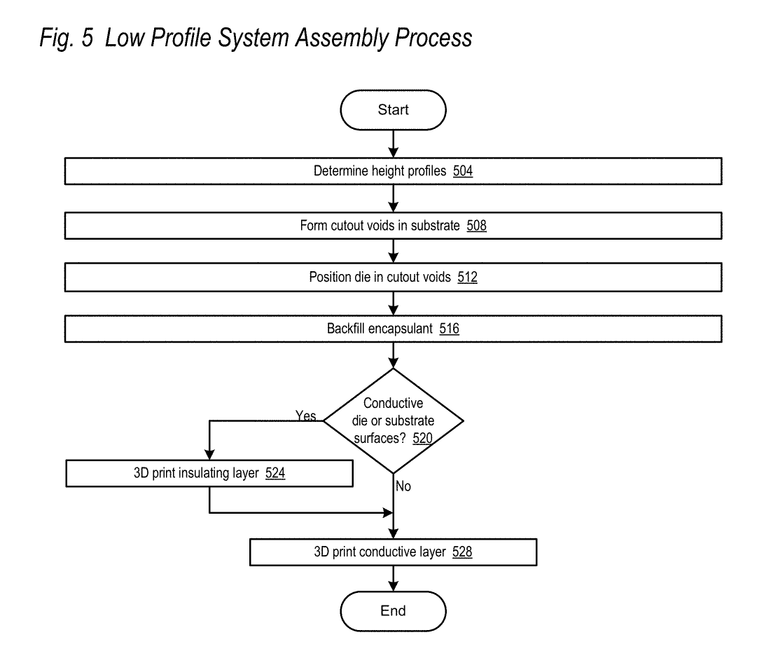

Referring now to FIG. 5, a flowchart illustrating a low profile system assembly process in accordance with a first embodiment of the present invention is shown. Flow begins at block 504.

At block 504, height profiles for one or more dies 104 and a substrate or printed circuit board 108 are determined. In a first embodiment, the existing height or thickness of the one or more dies 104 is the same as or very similar to the existing height of the substrate or printed circuit board 108. In a second embodiment, the existing height or thickness of the one or more dies 104 is less than the existing height of the substrate or printed circuit board 108. In a third embodiment, the existing height or thickness of the one or more dies 104 is greater than the existing height of the substrate or printed circuit board 108.

For the embodiments where the thicknesses of the one or more dies 104 and the substrate or printed circuit board 108 are different, it may be possible and desirable to reduce the thickness of the thicker of the dies 104 or substrate/printed circuit board 108 components. It is desirable to maintain similar thicknesses between the one or more dies 104 and the substrate or printed circuit board 108. Flow proceeds to block 508.

At block 508, cutouts 204, 304 and cutout voids 208 are formed in the substrate or printed circuit board 108. Each of the cutouts 204, 304 needs to be slightly larger than the die 104 intended to occupy each cutout 204, 304 in order for encapsulant 112 to flow within the cutout voids 208. Flow proceeds to block 512.

At block 512, each die 104 is positioned within a corresponding cutout 204, 304 and cutout voids 208. Preferably, each die 104 should be centered within the corresponding cutout 204, 304. Flow proceeds to block 516.

At block 516, encapsulant 112 is backfilled within the cutout voids 208 around each die 104. For embodiments where a portion of the substrate or printed circuit board 108 is below the die 104, it is desirable to make sure that encapsulant 112 fills the gap below the die 104 in order to remove air or moisture pockets. Alternately, the encapsulant 112 may be applied to the bottom of the cutout 304 prior to positioning the die 104 within the cutout 304. Flow proceeds to decision block 520.

At decision block 520, following encapsulant 112 application and at least partial curing, if there are conductive die 104 and substrate or printed circuit board 108 surfaces, then flow proceeds to block 524. If there are not conductive die 104 and substrate or printed circuit board 108 surfaces, then flow instead proceeds to block 528.

At block 524, a 3D printed insulating layer 128 is applied to conductive surfaces of the die 104, the substrate or printed circuit board 108, or both. Flow proceeds to block 528.

At block 528, a 3D printed conductive layer 132 is applied over the 3D printed insulating layer 128 in block 524, or directly to surfaces of the die 104, encapsulant 112, and a top surface of the substrate or printed circuit board 108. Flow ends at block 528.

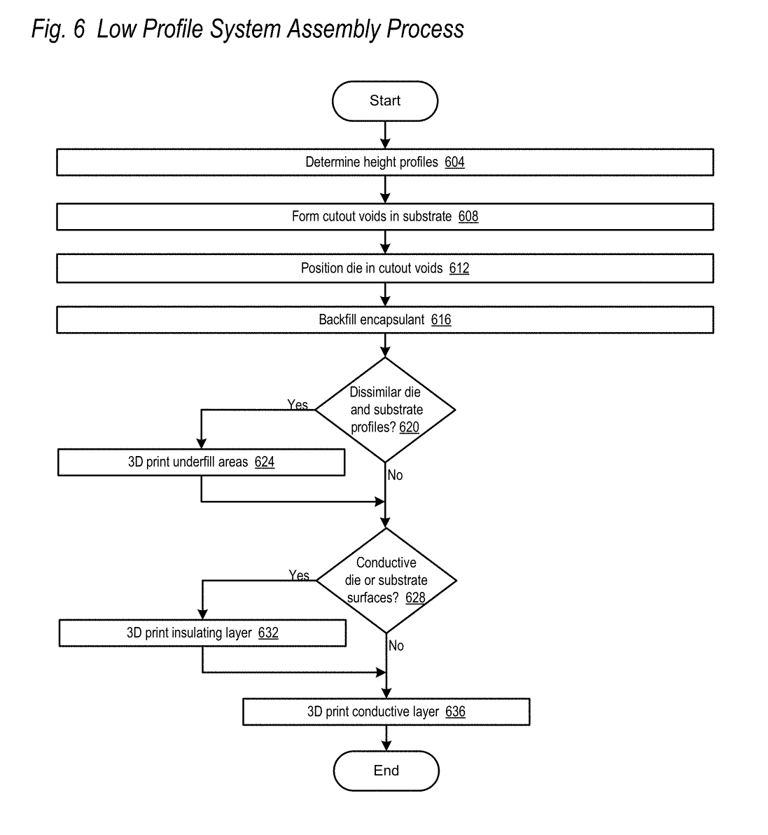

Referring now to FIG. 6, a flowchart illustrating a low profile system assembly process in accordance with a second embodiment of the present invention is shown. Flow begins at block 604.

At block 604, height profiles for one or more dies 104 and a substrate or printed circuit board 108 are determined. In a first embodiment, the existing height or thickness of the one or more dies 104 is the same as or very similar to the existing height of the substrate or printed circuit board 108. In a second embodiment, the existing height or thickness of the one or more dies 104 is less than the existing height of the substrate or printed circuit board 108. In a third embodiment, the existing height or thickness of the one or more dies 104 is greater than the existing height of the substrate or printed circuit board 108.

For the embodiments where the thicknesses of the one or more dies 104 and the substrate or printed circuit board 108 are different, and may be possible and desirable to reduce the thickness of the thicker of the dies 104 or substrate/printed circuit board 108 components. It is desirable to maintain similar thicknesses between the one or more dies 104 and the substrate or printed circuit board 108. Flow proceeds to block 608.

At block 608, cutouts 204, 304 and cutout voids 208 are formed in the substrate or printed circuit board 108. Each of the cutouts 204, 304 needs to be slightly larger than the die 104 intended to occupy each cut out 204, 304 in order for encapsulant 112 to flow within the cutout voids 208. Flow proceeds to block 612.

At block 612, each die 104 is positioned within a corresponding cutout 204, 304 and cutout voids 208. Preferably, each die 104 should be centered within the corresponding cutout 204, 304. Flow proceeds to block 616.

At block 616, encapsulant 112 is backfilled within the cutout voids 208 around each die 104. For embodiments where a portion of the substrate or printed circuit board 108 is below the die 104, it is desirable to make sure that encapsulant 112 fills the gap below the die 104 in order to remove air or moisture pockets. Alternately, the encapsulant 112 may be applied to the bottom of the cutout 304 prior to positioning the die 104 within the cutout 304. Flow proceeds to decision block 620.

At decision block 620, the thickness profiles of the die 104 and the substrate or printed circuit board 108 are compared in order to determine if underfill is required. If the height profiles of the die 104 and the substrate or printed circuit board 108 are dissimilar, then flow proceeds to block 624. If the height profiles of the die 104 and the substrate or printed circuit board 108 are not dissimilar, then flow instead proceeds to decision block 628.

At block 624, underfill areas between the die 104 and substrate or printed circuit board 108 are filled with either encapsulant material 112 or 3D printed bond insulator material 128. Flow proceeds to decision block 628.

At decision block 628, following encapsulant 112 application and at least partial curing, if there are conductive die 104 and substrate or printed circuit board 108 surfaces, then flow proceeds to block 632. If there are not conductive die 104 and substrate or printed circuit board 108 surfaces, then flow instead proceeds to block 636. Flow proceeds to block 632.

At block 632, a 3D printed insulating layer 128 is applied to conductive surfaces of the die 104, the substrate or printed circuit board 108, or both. Flow proceeds to block 636.

At block 636, a 3D printed conductive layer 132 is applied over the 3D printed insulating layer 128 in block 632, or directly to surfaces of the die 104, encapsulant 112, and a top surface of the substrate or printed circuit board 108. Flow ends at block 636.

Finally, those skilled in the art should appreciate that they can readily use the disclosed conception and specific embodiments as a basis for designing or modifying other structures for carrying out the same purposes of the present invention without departing from the spirit and scope of the invention as defined by the appended claims.

We claim:

1. A method, comprising:
forming a cutout in a substrate;
positioning an extracted die in a coplanar orientation with the substrate in the cutout, the extracted die removed from a previous packaged integrated circuit and comprising:
one or more original bond pads; and
one or more original ball bonds on the one or more original bond pads;
securing the extracted die in the cutout; and
3D printing, by a 3D printer, one or more bond connections between the one or more original bond pads and one or more connection points of the substrate or one or more bond pads of another die secured to the substrate.

2. The method of claim 1, wherein prior to forming the cutout, the method further comprising:
determining height profiles for the substrate and the extracted die.

3. The method of claim 2, wherein determining height profiles for the substrate and the extracted die comprises:
determining unmodified thicknesses of the substrate and the extracted die;
determining if either the substrate or the extracted die should be reduced in thickness in order to reduce the difference in thickness between the substrate and the extracted die.

4. The method of claim 3, wherein after determining height profiles for the substrate and the extracted die, the method further comprising:
reducing the thickness of the substrate or the extracted die if the difference in thickness between the substrate and the extracted die is greater than a predetermined amount.

5. The method of claim 1, wherein the substrate comprises a printed circuit board.

6. The method of claim 1, wherein the extracted die is secured within the cutout with one of an encapsulant, epoxy, or a die attach adhesive, wherein the extracted die is centered within the cutout.

7. The method of claim 1, wherein the 3D printed bond connections comprises bond conductors 3D printed over bond insulators, wherein the bond insulators electrically isolate the bond conductors from one or more of non-bond pad areas, connection point areas, and other bond conductors of the substrate and the extracted die.

8. The method of claim 7, wherein the 3D printed bond conductors completely covers bond pads of the extracted die and the other die.

9. The method of claim 7, wherein in response to an extracted die thickness being greater than a desired substrate thickness, the 3D printed bond insulators fill in thickness differences between the substrate and the extracted die.

10. A circuit, comprising:
a planar substrate, comprising a plurality of connection points;
a die, coplanarly secured within a cutout in the substrate, comprising a plurality of bond pads; and
a plurality of bond connections between the bond pads and the connection points, the bond connections conforming to all surfaces of the substrate and the die between the bond pads and the connection points.

11. The circuit of claim 10, wherein prior to securing the die within the cutout, determining unmodified thicknesses of the substrate and the die and determining if either the substrate or the die should be reduced in thickness in order to improve the coplanarity between the substrate and the die.

12. The circuit of claim 11, wherein in response to determining that either the substrate or the die should be reduced in thickness, reducing the thickness of the substrate or the die if the difference in thickness between the substrate and the die is greater than a predetermined amount.

13. The circuit of claim 10, wherein the die is secured with the cutout with one of an encapsulant, epoxy, or die attach adhesive, wherein the die is centered within the cutout.

14. The circuit of claim 10, wherein a depth of the cutout is less than the thickness of the substrate, wherein the depth of the cutout corresponds to a thickness of the die at the time the die is secured in the cutout.

15. The circuit of claim 10, wherein the bond connections comprises bond conductors 3D printed over bond insulators, wherein the bond insulators electrically isolate the bond conductors from one or more of non-bond pad and non-connection points areas or other bond conductors of the die and the substrate.

16. The circuit of claim 15, wherein bond insulators fill in thickness differences between the substrate and the die.

17. The circuit of claim 15, wherein each bond conductor completely covers one or more bond pads.

18. The circuit of claim 17, wherein a 3D printer forms the bond conductors as either a wider connection using a number of layers or a narrower connection using a greater number of layers than the wider connection.

19. A circuit, comprising:
a planar printed circuit board comprising connection points and a cutout;
an extracted die, removed from a previous packaged integrated circuit, comprising:
original bond pads; and
one or more original ball bonds on the original bond pads;
encapsulant to secure the die within the cutout in a generally coplanar orientation with the printed circuit board; and
bond connections between the original bond pads and one of the connection points or other bond pads of another die, the bond connections conforming to all surfaces of the printed circuit board, the extracted die, and the other die between the other bond pads and the connection points.

20. The circuit of claim 19, wherein the bond connections comprises bond conductors applied over bond insulators, wherein the bond insulators electrically isolate the bond conductors from one or more of non-bond pad and non-connection point areas and other bond conductors of the printed circuit board, the extracted die, and the other die.
